(19) United States
(12) Patent Application Publication
(10) Pub. No.: US 2010/0006912 A1
(43) Pub. Date: Jan. 14, 2010

(54) Planar Metal-Insulator-Metal Circuit Element and Method for Planar Integration of Same

(75) Inventors: Bradley J. Larsen, Mound, MN (US); Todd A. Randazzo, Mound, MN (US); Cheisan Yue, Roseville, MN (US)

Correspondence Address: HONEYWELL/S&S;Patent Services, 101 Columbia Road, P.O.Box 2245, Morristown, NJ, 07962-2245, US

(73) Assignee: HONEYWELL INTERNATIONAL INC., Morristown, NJ (US)

(21) Appl. No.: 12/368,900

(22) Filed: Feb. 10, 2009

Related U.S. Application Data
(60) Provisional application No. 61/080,548, filed on Jul. 14, 2008.

(51) Int. Cl. H01L 29/68; H01L 23/52; H01L 21/02

(52) U.S. Cl. 257/296; 438/598; 438/393; 257/E23.141; 257/E29.17; 257/379; 257/E21.008

(57) ABSTRACT

A complementary metal-oxide-semiconductor (CMOS) static random-access-memory (SRAM) element comprising a planar metal-insulator-metal (MIM) capacitor is disclosed, and the planar MIM capacitor is electrically connected to the transistors in the CMOS memory element to reduce the effects of charged particle radiation on the CMOS memory element. Methods for immunizing a CMOS SRAM element to the effects of charged particle radiation are also disclosed, along with methods for manufacturing CMOS SRAM including planar MIM capacitors as integrated circuits.

### CROSS-REFERENCE TO RELATED APPLICATIONS

The present patent application claims priority under 35 U.S.C. §119(e) to U.S. Provisional Patent Application Ser. No. 61/080,548 filed on Jul. 14, 2008, the entirety of which is herein incorporated by reference.

### FIELD OF INVENTION

The invention relates to electronic circuits arranged as memory cells, and more particularly, to memory cells capable of resisting errors caused by radiation. The invention also relates to methods for manufacturing electronic circuits arranged as memory cells capable of resisting errors caused by radiation.

### BACKGROUND

When charged particles, such as those found in heavy ion radiation, pass through a complementary metal-oxide-semiconductor (CMOS) memory cell, a state of data stored in the CMOS memory cell can change. This phenomenon, known as an “upset”, can be particularly problematic because the upset is often undetectable. As a result, data stored in a memory cell can be lost or altered. Such losses and alterations can cause a myriad of problems, including improper operation of software, erroneous results to calculations, and other errors.

A sensitivity of CMOS memory cells to upsets increases as the memory cells are scaled to smaller geometries and lower power supplies. Static random access memory (SRAM) cells that utilize silicon-on-insulator (SOI) field effect transistors (FETs) can be particularly sensitive to upsets caused by charged particle radiation when the SRAM cell is scaled to smaller geometries, for example. In addition, traditional methods of hardening SRAM memory cells can be difficult to implement within memory cells that are scaled to smaller device geometries.

### SUMMARY

In a first aspect, the present invention provides a complementary metal-oxide semiconductor (CMOS) static random access memory (SRAM) element comprising a plurality of metal-oxide semiconductor field-effect transistors (MOSFETs), wherein a planar metal-insulator-metal (MIM) capacitor is electrically connected to the CMOS SRAM element. In a second aspect, the present invention provides various methods for immunizing CMOS SRAM elements from the effects of charged particle radiation comprising, for example, electrically connecting a first node of a planar MIM capacitor to a first portion of the CMOS SRAM element and electrically connecting a second node of a planar MIM capacitor to a second portion of the CMOS SRAM element.

In a third aspect, the present invention provides methods for constructing CMOS SRAM elements as integrated circuits wherein a planar MIM capacitor is placed between a first interconnect layer of the integrated circuit and a second interconnect layer of the integrated circuit.

### BRIEF DESCRIPTION OF FIGURES

FIG. 1 depicts a schematic diagram of a memory cell in accordance with a first example embodiment of the invention.

FIG. 2 depicts a schematic diagram of a memory cell in accordance with a second example embodiment of the invention.

FIG. 3 depicts a schematic diagram of a memory cell in accordance with a third example embodiment of the invention.

FIG. 4 depicts a schematic diagram of a memory cell in accordance with a fourth example embodiment of the invention.

FIG. 5 depicts a schematic diagram of a memory cell in accordance with a fifth example embodiment of the invention.

FIG. 6 depicts a schematic diagram of a memory cell in accordance with a sixth example embodiment of the invention.

FIG. 7 depicts a schematic diagram of a memory cell in accordance with a seventh example embodiment of the invention.

FIG. 8 depicts a partial cross-sectional view of an example circuit incorporating a planar metal-insulator-metal capacitor in accordance with the invention.

FIG. 9 depicts a partial cross-sectional view of another example circuit incorporating a planar metal-insulator-metal capacitor in accordance with the invention.

FIGS. 10A-10D depict a series of partial cross-sectional views of a circuit during several stages of an example manufacturing process in accordance with the invention.

FIGS. 11A-11E depict a series of partial cross-sectional views of a circuit during several stages of another example manufacturing process in accordance with the invention.

### DETAILED DESCRIPTION OF EXEMPLARY EMBODIMENTS

When charged particles, such as those found in heavy ion radiation, pass through a CMOS memory element, the memory cell can change state, resulting in a loss or alteration of data stored in the memory cell, and is referred to as a single event upset (SEU) or a charged particle upset. The susceptibility of a CMOS memory cell to charged particle upsets increases as the cell is scaled to smaller geometries and designed to use lower power supplies. While SRAM cells that utilize silicon-on-insulator (SOI) FETs are typically less sensitive to charged particle upsets, they also exhibit increased sensitivity when the SRAM cells are scaled to smaller geometries and lower power supply voltages.

Exemplary methods of improving immunity to charged particle upsets include the addition of capacitors to the SRAM memory cell, such as a planar metal-insulator-metal (MIM) capacitor. A planar MIM capacitor structure comprises a top plate, a dielectric layer, and a bottom plate. The top and bottom plates are made of a metal or metal alloy. In example implementations, the metal or metal alloy used is tantalum nitride, titanium nitride, copper, or aluminum copper. However, any metal that satisfies the design requirements of a particular circuit or manufacturing process may be used to form the top and/or bottom plate of the planar MIM capacitor. The top plate and the bottom plate of an individual planar MIM capacitor need not be constructed from the same material.

In addition, any dielectric material may be used for the dielectric layer placed between the top plate and the bottom plate. For example, aluminum oxide or silicon dioxide may be used.

The use of materials with a high dielectric coefficient in the dielectric layer may be particularly advantageous in a planar MIM capacitor, permitting the formation of a planar MIM capacitor with a relatively high capacitance while maintaining a relatively small device size. In example implementations of planar MIM capacitors, the dielectric material used to form the dielectric layer typically has a dielectric constant of between about 3 and about 300. However, materials with higher or lower dielectric constants may be used, depending on the requirements of the circuit and/or the manufacturing process.

Planar MIM capacitors are compatible with many circuit manufacturing processes, including but not limited to copper back-end-of-the-line (BEOL) processes. Further, planar MIM capacitors can be used with CMOS SRAM cells built in various material technologies, including but not limited to bulk silicon, and silicon-on-insulator (SOI).

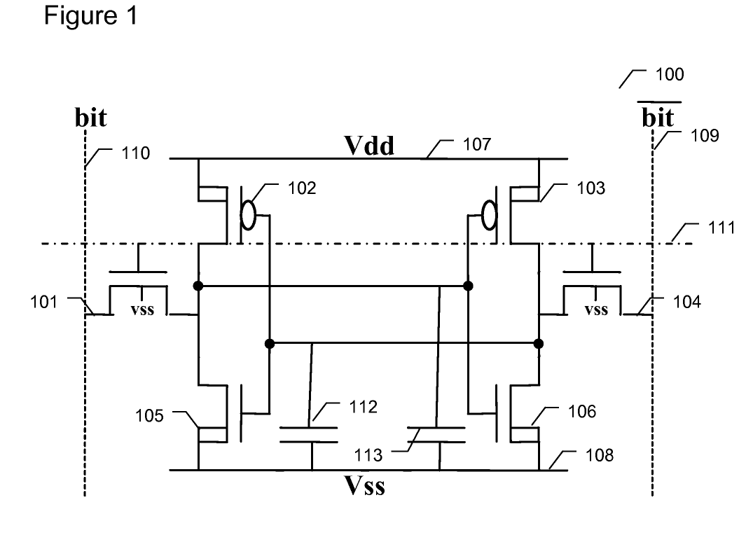

FIG. 1 depicts a schematic diagram of an example CMOS SRAM element 100 that incorporates planar MIM capacitors in accordance with a first aspect of the invention. SRAM element 100 comprises six metal-oxide-semiconductor field-effect transistors (MOSFETs) 101-106. As is well known in the art, p-type MOSFETs 102 and 103 are electrically connected to n-type MOSFETs 105 and 106 to form a pair of cross-connected inverters. A higher-voltage power supply rail 107, known in the art as Vdd, typically acts as a voltage supply and is electrically connected to p-type MOSFETs 102 and 103. A lower-voltage power supply rail 108, known in the art as Vss, may act as a voltage supply or a reference voltage and is electrically connected to n-type MOSFETs 105 and 106. Wordline 111 is electrically connected to the gates of access transistors 101 and 104. As is well known in the art, wordline 111 can be used to control the access transistors 101 and 104. Access transistor 101 is electrically connected to bitline 110, and access transistor 104 is electrically connected to inverse bitline 109. Through the control of wordline 111, bitline 110 and inverse bitline 109, read and write operations can be performed on the SRAM element 100.

Capacitors 112 and 113 are planar MIM capacitors. In the configuration shown in FIG. 1, capacitor 112 is electrically connected to the SRAM element such that one node of capacitor 112 is electrically connected to supply rail 108 and another node of capacitor 112 is electrically connected to a node where the gates of MOSFETs 102 and 105 and the drains of MOSFETs 106, 103, and 111 are electrically connected together, known as a storage node. Similarly, one node of capacitor 113 is also connected to supply rail 108, and a second node of capacitor 113 is electrically connected to a storage node where the gates of MOSFETs 103 and 106 and the drains of MOSFETs 102, 105, and 101 are electrically connected together. In this configuration, capacitors 112 and 113 improve the immunity of the CMOS SRAM circuit to errors caused by charged particle upset by increasing the capacitance of both storage nodes, thus increasing the quantity of charge necessary to cause the CMOS SRAM element to lose a stored bit or change state.

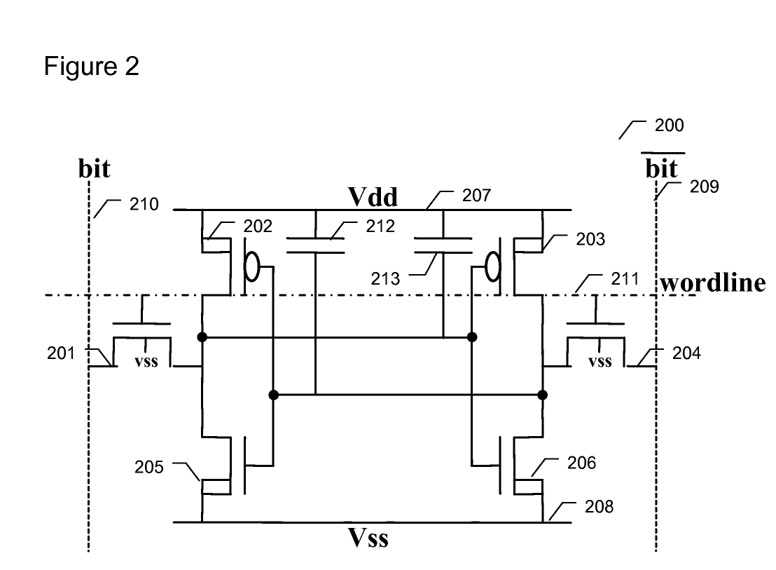

FIG. 2 depicts a schematic diagram of an example CMOS SRAM element 200. SRAM element 200 is similar to SRAM element 100 of FIG. 1 in that MOSFETs 201-206 are arranged in a manner similar to their counterpart MOSFETs 101-106 in SRAM element 100, and are similarly controlled by wordline 211, bitline 210, and inverse bitline 209. Unlike planar MIM capacitors 112 and 113 in FIG. 1 which are electrically connected to the lower-voltage supply rail 108, planar MIM capacitors 212 and 213 are electrically connected to the higher-voltage supply rail 207 rather than the lower-voltage supply rail 208. However, like planar MIM capacitors 112 and 113, planar MIM capacitors 212 and 213 increase the capacitance of both storage nodes, thus improving the immunity of SRAM element 200 to charged particle upset.

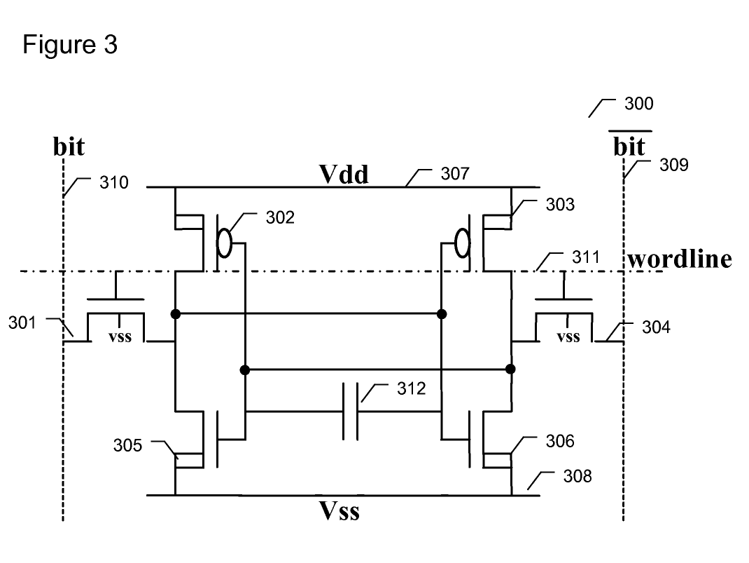

FIG. 3 depicts a schematic diagram of an example CMOS SRAM element 300. Similar to SRAM elements 100 and 200, MOSFETs 301-306 constitute a six-transistor SRAM memory element, electrically connected to supply rails 307 and 308, and capable of performing read and write operations in response to control signals received via wordline 311, bitline 310, and inverse bitline 309. However, SRAM element 300 differs from SRAM elements 100 and 200, shown in FIGS. 1 and 2 respectively, in that planar MIM capacitor 312 is arranged in SRAM element 300 such that one node of planar MIM capacitor 312 is electrically connected to one storage node, comprised of the gates of transistors 302 and 305 and the drains of transistors 303, 306, and 311, while another node of planar MIM capacitor 312 is connected to the other storage node comprised of the gates of transistors 303 and 306 and the drains of transistors 302, 305, and 301. In this arrangement, planar MIM capacitor 312 increases the capacitance of both storage nodes, and thus improves the immunity of the SRAM element 300 to charged particle upset.

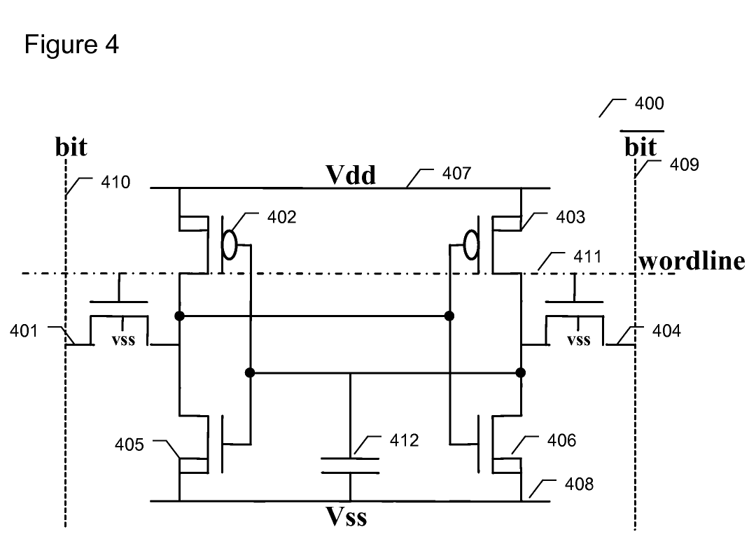

Planar MIM capacitors do not need to be electrically connected to all of the transistors in a CMOS SRAM element in order to improve the immunity of the SRAM element to charged particle upset. FIG. 4 depicts an SRAM element 400 wherein MOSFETs 401-406 are arranged and electrically connected to supply rails 407 and 408 as well as wordline 411, bitline 410, and inverse bitline 409 such that SRAM element 400 is capable of storing one bit of data and performing read and write operations. Planar MIM capacitor 412 is arranged in SRAM cell 400 such that one node of planar MIM capacitor 412 is electrically connected to the lower supply rail 408, and another node of planar MIM capacitor 412 is electrically connected to the storage node comprised of the gates of transistors 402 and 405 and the drains of transistors 403, 406, and 411. The depicted configuration of the planar MIM capacitor 412 provides increased immunity to charged particle upset by adding capacitance to a gate storage node. While planar MIM capacitor 412 is shown as being electrically connected to supply rail 408, immunity to charged particle upset could also be achieved by electrically coupling the planar MIM capacitor 412 to supply rail 407 instead of supply rail 408.

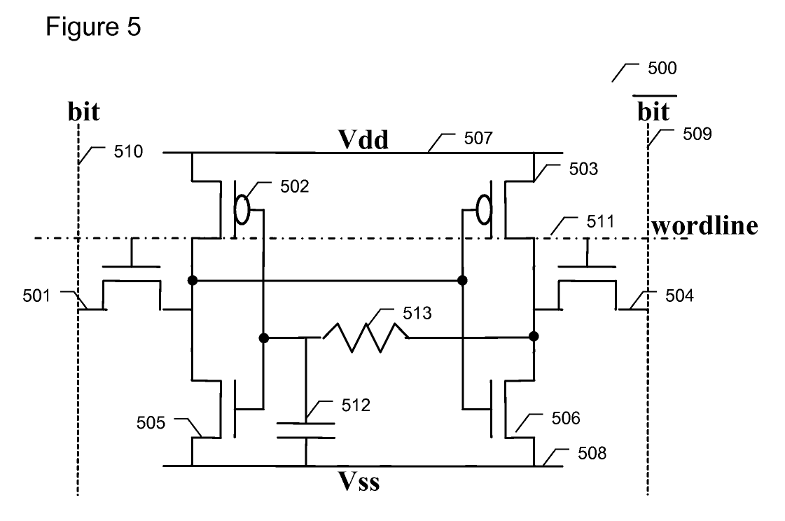

FIG. 5 depicts an SRAM element 500 wherein an RC delay is added to provide a level of immunity to charged particle upset. In addition to the CMOS SRAM element comprising MOSFETs 501-506, supply rails 507 and 508, wordline 511, bit line 510, and inverse bit line 509, SRAM element 500 includes planar MIM capacitor 512 and resistor 513. In this configuration, resistor 513 is used to isolate the input of one cross coupled inverter defined as the gates of transistors 502 and 505, which now is a storage node, from the output of the other inverter defined as the drains of transistors 503 and 506. One node of planar MIM capacitor 512 is electrically connected to the storage node consisting of one node of resistor 513 and the gates of MOSFETs 502 and 505. A second node of planar MIM capacitor 512 is electrically connected to supply rail 508. While planar MIM capacitor 512 is depicted as electrically connected to supply rail 508, a level of immunity to charged particle upset may also be achieved by electrically connecting planar MIM capacitor to supply rail 507 instead of supply rail 508. A second node of resistor 513 is electrically connected to the output of the opposing inverter consisting of the drains of transistors 503, 506, and 511. In this configuration, resistor 513 and planar MIM capacitor 512 form a delay element. The RC delay provided by the combination of resistor 513 and planar MIM capacitor 512 provides an increase in immunity to charged particle upset in part by increasing a feedback delay of the SRAM element.

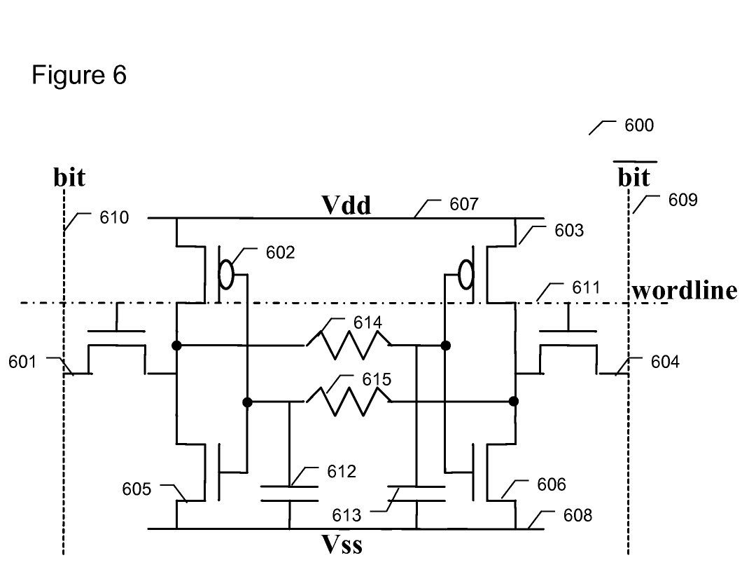

FIG. 6 depicts a schematic diagram of an example SRAM element that expands upon the implementation of an RC delay element shown in FIG. 5. SRAM element 600 includes MOSFETs 601-606 arranged to form a six-transistor CMOS SRAM circuit, including the appropriate electrical connections to supply rails 607 and 608, as well as wordline 611, bitline 610, and inverse bitline 609. SRAM element 600 also includes two delay elements. The first delay element is formed by planar MIM capacitor 612 and resistor 615. The second delay element is formed by planar MIM capacitor 613 and resistor 614. In this configuration, resistor 615 is used to isolate the input of one cross coupled inverter defined as the gates of transistors 602 and 605, which now is a storage node, from the output of the other inverter defined as the drains of transistors 603 and 606. Also in this configuration, resistor 614 is used to isolate the input of one cross coupled inverter defined as the gates of transistors 603 and 606, which now is a storage node, from the output of the other inverter defined as the drains of transistors 602 and 605.

The hookup of the first delay element consisting of planar MIM capacitor 612 and resistor 615 is as follows: One node of planar MIM capacitor 612 is electrically connected to the storage node consisting of one node of resistor 615 and the gates of MOSFETs 602 and 605. A second node of planar MIM capacitor 612 is electrically connected to supply rail 608. While planar MIM capacitor 612 is depicted as electrically connected to supply rail 608, a level of immunity to charged particle upset may also be achieved by electrically connecting planar MIM capacitor to supply rail 607 instead of supply rail 608. A second node of resistor 615 is electrically connected to the output of the opposing inverter consisting of the drains of transistors 603, 606, and 611.

The hookup of the second delay element consisting of planar MIM capacitor 613 and resistor 614 is as follows: One node of planar MIM capacitor 613 is electrically connected to the storage node consisting of one node of resistor 614 and the gates of MOSFETs 603 and 606. A second node of planar MIM capacitor 613 is electrically connected to supply rail 608. While planar MIM capacitor 613 is depicted as electrically connected to supply rail 608, a level of immunity to charged particle upset may also be achieved by electrically connecting planar MIM capacitor to supply rail 607 instead of supply rail 608. A second node of resistor 614 is electrically connected to the output of the opposing inverter consisting of the drains of transistors 602, 605, and 601. As with the delay element formed by planar MIM capacitor 512 and resistor 513 in FIG. 5, the delay elements formed by planar MIM capacitor 612 and resistor 615 and MIM capacitor 613 and resistor 614 provide an improved level of immunity to charged particle upset over CMOS SRAM elements that do not contain similarly arranged capacitors and/or resistors by increasing a feedback delay in the CMOS SRAM element.

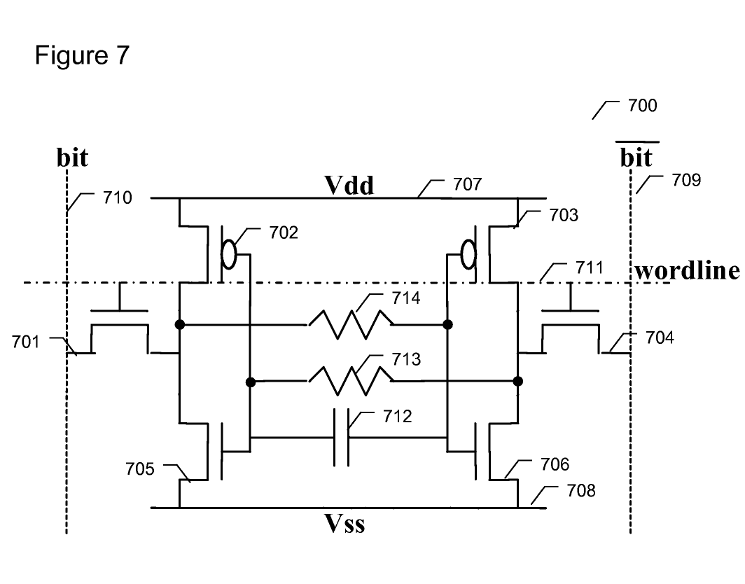

FIG. 7 depicts a schematic diagram of an example SRAM element that presents an alternate arrangement of resistors and capacitors to improve the immunity of the SRAM element to charged particle upset. SRAM element 700 includes MOSFETs 701-706 arranged to form a six-transistor CMOS SRAM circuit, including the appropriate electrical connections to supply rails 707 and 708, as well as wordline 711, bitline 710, and inverse bitline 709. SRAM element 700 also includes two resistors, 713 and 714. In this configuration, resistors 713 and 714 are again used to isolate the inputs and outputs of the cross coupled inverters. Resistor 713 is arranged such that a first node of resistor 713 is electrically connected to the storage node consisting of one node of the planar MIM capacitor 712 and the gates of transistors 702 and 705, while the other node of resistor 713 is electrically connected to the output of the opposing inverter consisting of the drains of transistors 703, 706, and 711. Resistor 714 is arranged such that a first node of resistor 714 is electrically connected to the storage node consisting of one node of the planar MIM capacitor 712 and the gates of transistors 703 and 706, while the other node of resistor 714 is electrically connected to the output of the opposing inverter consisting of the drains of transistors 702, 705, and 701. Thus planar MIM capacitor 712 is connected between the two storage nodes.

FIGS. 1-7 represent a non-exclusive collection of example embodiments of CMOS

SRAM elements that include one or more planar MIM capacitor added to the circuit to improve the immunity of the CMOS SRAM element to charged particle upset. Those skilled in the art will appreciate and understand that numerous other arrangements of one or more planar MIM capacitors in a CMOS SRAM element may be used to increase the immunity of the CMOS SRAM element to charged particle upset. Further, while the example CMOS SRAM elements depicted in FIGS. 1-7 utilize six transistors, the invention is not limited to six-transistor CMOS SRAM elements. Rather, planar MIM capacitors may be used with CMOS SRAM elements that use any number of transistors, including without limitation five-, seven-, eight-, nine-, and ten-transistor CMOS SRAM elements.

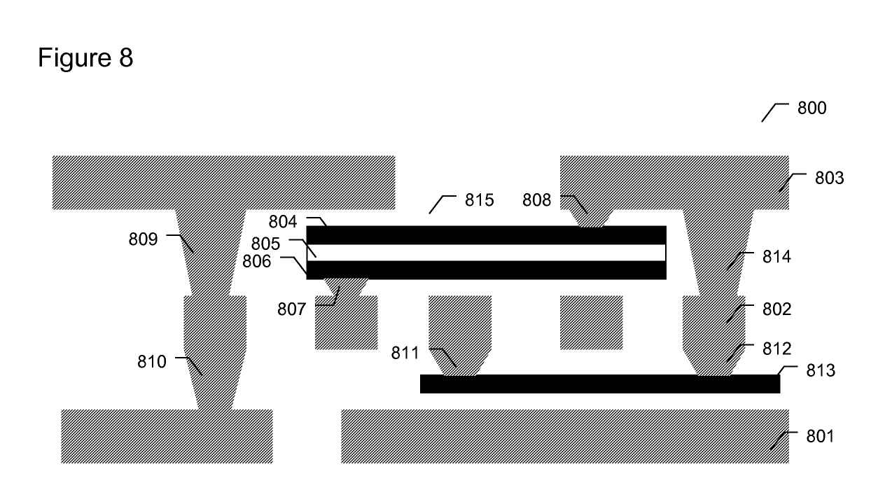

One of the advantages of planar MIM capacitors is that the planar MIM capacitor can be positioned between interconnect layers in a circuit. FIG. 8 depicts a partial cross-sectional view of a circuit 800. Circuit 800 may be constructed using a copper back-end-of-the-line (BEOL) manufacturing process, or any other manufacturing process wherein electrical components and connections between electrical components are deposited and/or etched onto a wafer. The manufacturing process may involve the use of bulk silicon, silicon-on-insulator (SOI) or any other material used for electronics manufacturing known now or developed later.

The partial cross-sectional view of circuit 800 depicts three interconnect layers, known in the art as an M3 layer 801, an M4 layer 802, and an M5 layer 803. In general, an inter-layer dielectric material is deposited between layers 801, 802, and 803 to prevent the layers 801-803 from forming inadvertent electrical connections, and otherwise to facilitate the manufacturing process. As is well known in the art, pathways establishing electrical connections between electrical components and/or other circuit elements can be implemented on each of layers 801-803, and electrical connections may be established between layers 801-803 through the use of interconnecting vias. In circuit 800, vias 809 and 814 establish electrical connections between M4 layer 802 and M5 layer 803, while via 810 establishes an electrical connection between M4 layer 802 and M3 layer 801.

Circuit 800 includes planar MIM capacitor 815, which is positioned in the inter-layer dielectric material between M4 layer 802 and M5 layer 803. Planar MIM capacitor 815 comprises top plate 804, dielectric layer 805, and bottom plate 806. As described above, any electrically conductive metal, metal alloy, or combination of metals may be used to form top plate 804 and bottom plate 806. In example embodiments, the metals and metal alloys used to for top and bottom plates such as top plate 804 and bottom plate 806 include, without limitation, tantalum nitride, titanium nitride, copper, and aluminum copper. Any insulating material may be used to form dielectric layer 805, including, without limitation, materials with a high dielectric constant. In example embodiments, materials used to form dielectric layer 805 include, without limitation, aluminum oxide and silicon dioxide. In other example embodiments, the material used to form dielectric layer 805 can be characterized as having a dielectric constant between about 3 and about 300, though materials with dielectric constants above 300 may also be used for dielectric layers such as dielectric layer 805. As shown in FIG. 8, an electrical connection is established between top plate 804 and M5 layer 803 by via 808. Similarly, an electrical connection is established between bottom plate 806 and M4 layer 802 by via 807.

Since planar MIM capacitor 815 can be placed between interconnect layers, planar MIM capacitors such as planar MIM capacitor 815 can be used to add capacitance to a circuit without reducing or substantially reducing the space available on the interconnect layers such as layers 801-803 for establishing electrical connections or routing signals through the circuit. Further, since planar MIM capacitors can be placed in any space between interconnect layers, planar MIM capacitors can be positioned above other components in a circuit. For example, when manufacturing a CMOS SRAM element, such as any of the example elements depicted in FIGS. 1-7, the use of planar MIM capacitors allows for the addition of capacitance, which can improve the immunity of the CMOS SRAM element to charged particle upset, without using any space on the layer with MOSFETs for a capacitor. By eliminating the need to reserve space for a capacitor on any particular layer, the use of one or more planar MIM capacitors permits the MOSFETs in the SRAM element to be placed more closely together, which can improve the performance of the SRAM element and reduce the amount area required to form the SRAM element. Further, in SRAM elements or other circuits that benefit from symmetrical circuit layouts, the use of planar MIM capacitors in between layers may facilitate symmetrical layouts that are difficult or impossible when using other capacitor structures.

Another advantage of planar MIM capacitors is the ability to vertically stack multiple planar MIM capacitors or other components in multiple interconnect layers. In FIG. 8, resistor 813 is located between M3 layer 801 and M4 layer 802, and is electrically connected to two different portions of M4 layer 804 through vias 811 and 812. While element 813 in example circuit 800 is a resistor, element 813 could be another circuit element, such as a planar MIM capacitor similar in structure to planar MIM capacitor 815. For example, if an example circuit required more capacitance than a first planar MIM capacitor could provide, a second planar MIM capacitor could be placed in the space between two other interconnect layers and electrically connected to the first planar MIM capacitor to provide the additional capacitance. When achieving an increased amount of capacitance by stacking planar MIM capacitors, it may also be possible to use the same photo masks for each planar MIM capacitor in a given portion of a circuit, which may decrease the manufacturing costs of a particular circuit.

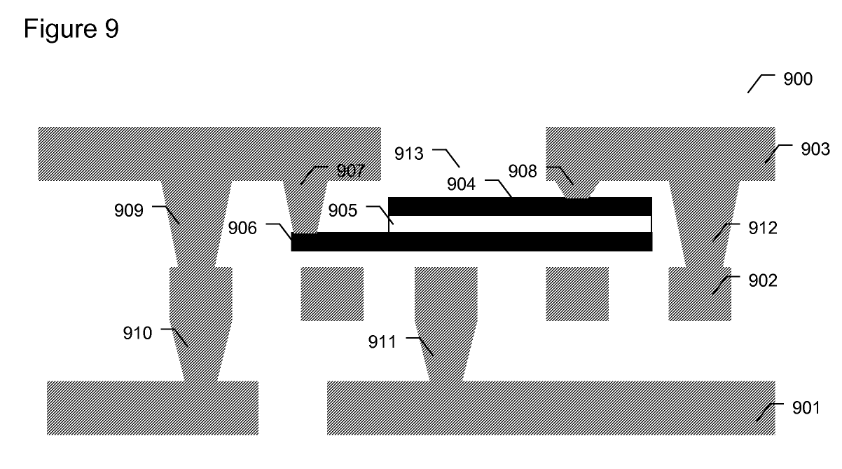

FIG. 9 provides another partial cross-sectional view of a circuit utilizing a planar MIM capacitor between two interconnect layers. Layers 901, 902, and 903 are interconnect layers M3, M4, and M5, respectively, and electrical connections between layers 901-903 are established by vias such as vias 909, 910, 911, and 912. Planar MIM capacitor 913 comprises a top plate 904, a dielectric layer 905, and a bottom plate 906. Via 908 establishes an electrical connection between M5 layer 903 and top plate 904. Via 907 establishes a connection with bottom plate 906. While example circuits 800 and 900 depict two possible arrangements of planar MIM capacitors in a circuit, the depicted embodiments are non-limiting examples. Those skilled in the art will appreciate and recognize that numerous other arrangements of planar MIM capacitors and connections between planar MIM capacitors and other electrical components and/or portions of a circuit may be implemented without departing from the scope of the invention. Further, while planar MIM capacitors 815 and 913 are depicted as being placed between interconnect layers known as M4 and M5, planar MIM capacitors can be placed between any two vertically adjacent interconnect layers of a circuit without departing from the scope of the invention.

In some implementations where a planar MIM capacitor is added to a circuit between interconnect layers, the addition of a planar MIM capacitor may cause a portion of the circuit to be thicker than surrounding portions of the circuit, resulting in reduced planarization between regions of a circuit with planar MIM capacitors and regions of a circuit without planar MIM capacitors. In manufacturing processes that require a high degree of planarization on a given layer, this reduction in planarization may lead to process issues such as non-uniformity in photo processes and etch processes.

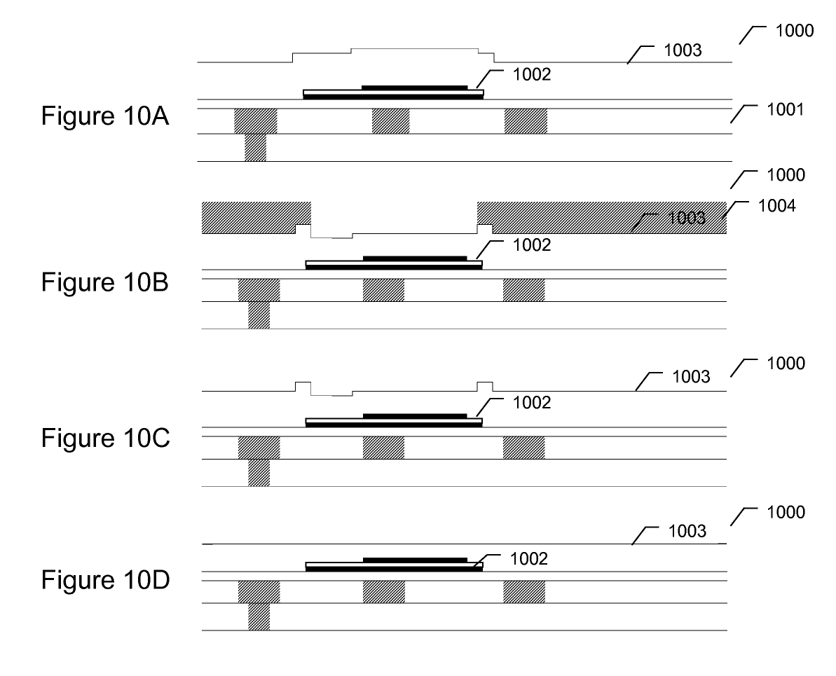

One method of attenuating a reduction in planarization caused by the introduction of a planar MIM capacitor comprises using a reverse tone mask and etching a portion of the inter-layer dielectric material deposited over the planar MIM capacitor. FIG. 10A depicts an example circuit 1000 that utilizes a planar MIM capacitor 1002 that is physically located above one or more circuit layers 1001. As shown in FIG. 10A, a layer of inter-layer dielectric (ILD) material 1003 has been deposited over planar MIM capacitor 1002, resulting in a reduction in planarization in ILD material 1003 that generally follows the contours of planar MIM capacitor 1002.

FIG. 10B depicts a subsequent step in the manufacturing process of example circuit 1000. A reverse tone photo-resist mask is applied over a portion of ILD material 1003, but is not applied to the region directly over planar MIM capacitor 1002. An etching process is then applied to remove some of the ILD material from the region above planar MIM capacitor 1002, while photo-resist mask 1004 prevents the removal of ILD material from other portions of circuit 1000. After etching, photo-resist mask 1004 can be removed, revealing a profile similar to the profile depicted in FIG. 10C.

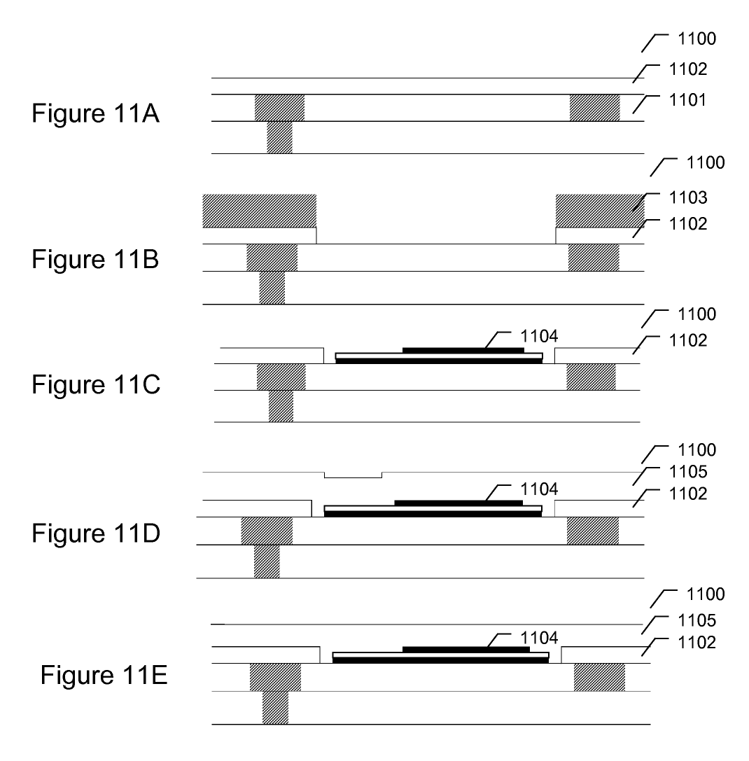

In FIG. 10C, the reduction in the planarization of ILD material 1003 in example circuit 1000 is already attenuated when compared to FIG. 10A. However, as depicted in FIG. 10C, non-uniformities in the relative planarity of ILD material 1003 may still remain in the region above planar MIM capacitor 1002. By applying a chemical-mechanical planarization (CMP) process, such remaining non-uniformities in the relative planarity of ILD material 1003 may be further reduced, resulting in a profile similar to the profile depicted in FIG. 10D. In FIG. 10D, example circuit 1000 has undergone a CMP process. As a result, the top of ILD material 1003 conforms to a planar or nearly planar profile, while circuit 1000 retains the benefits derived by including a planar MIM capacitor such as planar MIM capacitor 1002. Planarization of an ILD layer may also be improved by implementing a manufacturing process similar to the process depicted in FIGS. 11A-11E. FIG. 11A depicts a partial cross-sectional view of example circuit 1100, wherein a first ILD material layer 1102 has been deposited over a circuit layer 1101. The thickness of the first ILD material layer 1102 may vary depending on the manufacturing criteria of example circuit 1100. In an example implementation of the manufacturing method, ILD material layer 1102 has a thickness substantially equal to the thickness of a planar MIM capacitor that will be added to the circuit.

In FIG. 11B, reverse tone photo-resist mask 1103 has been applied over a portion of the first ILD material layer 1102. Photo-resist mask 1103 is not applied over the region of first ILD material layer 1102 where a planar MIM capacitor will be installed. After photo-resist mask 1103 is applied to first ILD material layer 1102, an etching process is used to remove the portion of first ILD material layer 1102 that was not covered by photo-resist mask 1103. Subsequent to the completion of the etching process, the photo-resist mask 1103 is removed.

After removal of photo-resist mask 1103, planar MIM capacitor 1104 can be installed in example circuit 1100, as depicted in FIG. 11C, wherein planar MIM capacitor 1104 fits in the space created by etching away a portion of first ILD material layer 1102. After planar MIM capacitor 1104 is installed, second ILD material layer 1105 can be deposited over planar MIM capacitor 1104 and first ILD material layer 1103. As shown in FIG. 11D the profile of second ILD material layer 1105 generally follows the contour of planar MIM capacitor 1104 and first ILD material layer 1103. In implementations where the thicknesses of planar MIM capacitor 1104 and first ILD material layer 1103 are similar, such as in FIG. 11D, the profile of second ILD material layer 1105 may be somewhat planar. However, if any remaining non-uniformities in the relative planarity of second ILD material layer 1105 are unacceptable based on the needs of a particular implementation of the manufacturing process, a CMP process may be applied to example circuit 1100, resulting in the highly planar profile of second ILD material layer 1105 depicted in FIG. 11E.

The processes depicted in FIGS. 10A-10D and 11A-11E represent non-limiting examples of manufacturing methods that may be used when constructing circuits that contain planar MIM capacitors. Those skilled in the art will appreciate and recognize that the described steps may be reordered, repeated, and/or combined with other processes without departing from the scope of the invention. Further, those skilled in the art will appreciate that circuits utilizing planar MIM capacitors may be implemented using the described steps, circuits utilizing planar MIM capacitors in accordance with the invention may also be implemented using other processes.

Various arrangements and embodiments in accordance with the present invention have been described herein. All embodiments of each aspect of the invention can be used with embodiments of other aspects of the invention. It will be appreciated, however, that those skilled in the art will understand that changes and modifications may be made to these arrangements and embodiments, as well as combinations of the various embodiments without departing from the true scope and spirit of the present invention, which is defined by the following claims.

What is claimed is:

1. A complementary metal-oxide-semiconductor (CMOS) memory element comprising a plurality of metal-oxide-semiconductor field-effect transistors (MOSFETs) and a planar metal-insulator-metal (MIM) capacitor, wherein the planar MIM capacitor is electrically connected to at least one of the plurality of MOSFETs in the CMOS memory element.

2. The CMOS memory element of claim 1 wherein two of the plurality of MOSFETs are electrically connected to form a gate storage node and a first node of the planar MIM capacitor is electrically connected to the gate storage node in the CMOS memory element and a second node of the planar MIM capacitor is electrically connected to a voltage supply in the CMOS memory element.

3. The CMOS memory element of claim 2 further comprising a resistor, wherein the first node of the planar MIM capacitor is electrically connected to a node of the resistor.

4. The CMOS memory element of claim 1 wherein the plurality of MOSFETs are electrically connected to form a first gate storage node and a second gate storage node, and a first node of the planar MIM capacitor is electrically connected to the first gate storage node and a second node of the planar MIM capacitor is electrically connected to the second gate storage node.

5. The CMOS memory element of claim 4 further comprising a resistor, wherein the first node of the planar MIM capacitor is electrically connected to a node of the resistor.

6. The CMOS memory element of claim 1 wherein the CMOS memory element is constructed on a bulk silicon substrate.

7. The CMOS memory element of claim 1 wherein the CMOS memory element is constructed on a silicon-on-insulator (SOI) substrate.

8. The CMOS memory element of claim 1 wherein the CMOS memory element is constructed as an integrated circuit.

9. A method for immunizing a complementary metal-oxide-semiconductor (CMOS) static random access memory (SRAM) element from charged particle radiation comprising:
electrically connecting a first node of a planar metal-insulator-metal (MIM) capacitor to a first portion of the CMOS SRAM element; and
electrically connecting a second node of the planar MIM capacitor to a second portion of the CMOS SRAM element.

10. The method of claim 11 wherein electrically connecting a first node of a planar MIM capacitor to a first portion of the CMOS SRAM element comprises electrically connecting the first node of the planar MIM capacitor to a voltage supply in the CMOS SRAM element.

11. The method of claim 10 wherein electrically connecting a second node of a planar MIM capacitor to a second portion of the CMOS SRAM element comprises electrically connecting the second node of the planar MIM capacitor to a gate storage node in the CMOS SRAM element.

12. The method of claim 9 wherein electrically connecting a first node of a planar MIM capacitor to a first portion of the CMOS SRAM element comprises electrically connecting the first node of the planar MIM capacitor to a first gate storage node in the CMOS SRAM element.

13. The method of claim 12 wherein electrically connecting a second node of a planar MIM capacitor to a second portion of the CMOS SRAM element comprises electrically connecting the second node of the planar MIM capacitor to a second gate storage node in the CMOS SRAM element.

14. The method of claim 9 wherein the CMOS SRAM element comprises a resistor, and electrically connecting a first node of a planar MIM capacitor to a first portion of the CMOS SRAM element comprises electrically connecting the first node of the planar MIM capacitor to a node on the resistor.

15. The method of claim 9 further comprising incorporating the CMOS SRAM element and planar MIM capacitor into an integrated circuit.

16. The method of claim 9 wherein the CMOS SRAM memory element is constructed using a back-end-of-the-line (BEOL) manufacturing process.

17. A method for constructing a complementary metal-oxide-semiconductor (CMOS) static random access memory (SRAM) element as an integrated circuit comprising placing a planar metal-insulator-metal (MIM) capacitor in a space between a first interconnect layer of an integrated circuit and a second interconnect layer of the integrated circuit.

18. The method of claim 17 wherein placing a planar MIM capacitor in a space between a first interconnect layer of an integrated circuit and a second interconnect layer of the integrated circuit comprises:
placing the planar MIM capacitor on the first interconnect layer of the integrated circuit;
applying a layer of inter-layer dielectric (ILD) material over the planar MIM capacitor and a portion of the first interconnect layer;
applying a reverse tone photo-resist mask to the ILD material positioned over the portion of the first interconnect layer and not to the ILD material positioned over the planar MIM capacitor;
etching away a portion of the ILD material positioned over the planar MIM capacitor;
removing the reverse tone photo-resist mask; and
performing a chemical-mechanical planarization (CMP) process on the integrated circuit.

19. The method of claim 17 wherein placing a MIM capacitor in a space between a first interconnect layer of an integrated circuit and a second interconnect layer of the integrated circuit comprises:
depositing a first layer of ILD material over the first interconnect layer of the integrated circuit;
applying a reverse tone photo-resist mask over a portion of the first layer of ILD material and not over a region of the ILD material corresponding to an intended position for the planar MIM capacitor;
etching away a portion of the first layer of ILD material;
removing the reverse tone photo-resist mask;
placing the planar MIM capacitor in a region of the integrated circuit where a portion of the first layer of ILD material was etched away;
applying a second layer of ILD material over the planar MIM capacitor and the first layer of ILD material; and
applying a chemical-mechanical planarization (CMP) process to the integrated circuit.

20. The method of claim 19 wherein a thickness of the first layer of ILD material is substantially equal to a thickness of the planar MIM capacitor.
